(19) United States
(12) Patent Application Publication
(10) Pub. No.: US 2026/0075909 A1
(43) Pub. Date: Mar. 12, 2026

(54) SEMICONDUCTOR DEVICE AND METHOD FOR MANUFACTURING THE SAME

(71) Applicants: Kabushiki Kaisha Toshiba, Tokyo (JP); Toshiba Electronic Devices & Storage Corporation, Tokyo (JP)

(72) Inventors: Shota SUZUKI, Nonoichi Ishikawa (JP); Takeshi SHIBATA, Nonoichi Ishikawa (JP)

(21) Appl. No.: 19/040,530

(22) Filed: Jan. 29, 2025

(30) Foreign Application Priority Data
Sep. 11, 2024 (JP) 2024-157600

(51) Int. Cl. H10D 64/01; H01L 21/28; H10D 30/01; H10D 30/66; H10D 64/00; H10D 64/27

(52) U.S. Cl. CPC H10D 64/025; H10D 30/0297; H10D 30/668; H10D 64/01338; H10D 64/518; H10D 64/117; H10D 64/513

(57) ABSTRACT

According to an embodiment, a semiconductor device includes a first electrode, and a gate electrode, first and second insulating portions, and a second electrode. The semiconductor portion has a trench that extends along a first direction. The semiconductor portion includes first to third semiconductor layers. The gate electrode is disposed in the trench so as to face the second semiconductor layer and the third semiconductor layer along a second direction orthogonal to the first direction. The gate electrode has a facing surface formed at a position facing the third semiconductor layer so as to be away from the third semiconductor layer as the facing surface extends upward. The first insulating portion is continuously provided on the semiconductor portion and inside the trench. The second insulating portion is provided on the gate electrode. A material of the second insulating portion is different from a material of the first insulating portion.

### CROSS-REFERENCE TO RELATED APPLICATIONS

This application is based upon and claims the benefit of priority from Japanese Patent Application No. 2024-157600, filed on Sep. 11, 2024; the entire contents of which are incorporated herein by reference.

### FIELD

Embodiments of the invention generally relate to a semiconductor device and a method for manufacturing the same.

### BACKGROUND

A technique related to a MOS (metal-oxide-semiconductor) having a trench structure has been developed.

### BRIEF DESCRIPTION OF THE DRAWINGS

FIG. 1 is a plan view of a semiconductor device according to an embodiment;

FIG. 2 is a cross-sectional view of a region D1 at a height L1;

FIG. 3 is a cross-sectional view of the region D1 at a height L2;

FIG. 4 is a cross-sectional view of the region D1 at a height L3;

FIG. 5 is a cross-sectional view taken along line V-V in FIG. 2 to FIG. 4;

FIG. 6 is an enlarged view of a region D4;

FIG. 7 is a cross-sectional view taken along line VII-VII in FIG. 2 to FIG. 4;

FIG. 8 is a cross-sectional view taken along line VIII-VIII in FIG. 2 to FIG. 4;

FIG. 9 is a perspective view schematically showing a region D2;

FIG. 10 is a perspective view schematically showing a structure of a part of a region D3;

FIGS. 11A to 11C are cross-sectional views showing a method for manufacturing the semiconductor device according to the embodiment;

FIGS. 12A to 12C are cross-sectional views showing the method for manufacturing the semiconductor device according to the embodiment;

FIGS. 13A to 13C are cross-sectional views showing the method for manufacturing the semiconductor device according to the embodiment;

FIGS. 14A to 14C are cross-sectional views showing the method for manufacturing the semiconductor device according to the embodiment;

FIGS. 15A to 15C are cross-sectional views showing the method for manufacturing the semiconductor device according to the embodiment;

FIGS. 16A to 16C are cross-sectional views showing the method for manufacturing the semiconductor device according to the embodiment;

FIGS. 17A to 17C are cross-sectional views showing the method for manufacturing the semiconductor device according to the embodiment;

FIGS. 18A to 18C are cross-sectional views showing the method for manufacturing the semiconductor device according to the embodiment;

FIGS. 19A to 19C are cross-sectional views showing the method for manufacturing the semiconductor device according to the embodiment;

FIGS. 20A to 20C are cross-sectional views showing the method for manufacturing the semiconductor device according to the embodiment; and

FIGS. 21A to 21C are cross-sectional views showing the method for manufacturing the semiconductor device according to the embodiment.

### DETAILED DESCRIPTION

According to an embodiment, a semiconductor device includes a first electrode, a semiconductor portion, a gate electrode, a first insulating portion, a second insulating portion, and a second electrode.

The semiconductor portion is provided on the first electrode and has a trench formed therein. The trench extends along a first direction. The semiconductor portion includes a first semiconductor layer of a first conductivity type, a second semiconductor layer of a second conductivity type, and a third semiconductor layer of the first conductivity type. The first semiconductor layer is connected to the first electrode. The second semiconductor layer is provided on the first semiconductor layer. The third semiconductor layer is provided on the second semiconductor layer. The gate electrode is disposed in the trench. The gate electrode faces the second semiconductor layer and the third semiconductor layer along a second direction orthogonal to the first direction. The gate electrode has a facing surface formed at a position facing the third semiconductor layer. A distance between the facing surface and the third semiconductor layer in the second direction increases as it extends upward. The first insulating portion is continuously provided on the semiconductor portion and inside the trench. The second insulating portion is provided on the gate electrode. A material of the second insulating portion is different from a material of the first insulating portion. The second electrode is provided on the semiconductor portion and connected to the second semiconductor layer and the third semiconductor layer.

According to another embodiment, a method for manufacturing a semiconductor device includes forming a silicon nitride film on a structure. The structure including a semiconductor portion, a gate electrode, and an insulating portion. The semiconductor portion has a trench formed therein. The trench extends along a first direction. The semiconductor portion contains silicon. The gate electrode is provided in the trench and contains silicon. The insulating portion is disposed between the semiconductor portion and the gate electrode. The structure has a recessed portion formed on the gate electrode. The method further includes forming a silicon oxide film on the silicon nitride film. The method further includes removing the silicon oxide film in a region other than a region immediately above the recessed portion by performing a planarization process. The method further includes etching the silicon nitride film while using the silicon oxide film above the recessed portion as a mask. The method further includes performing oxidation treatment on the gate electrode.

Embodiments of the invention will now be described with reference to the drawings. The embodiments are not intended to limit the invention. The drawings are schematic or conceptual and, for example, the proportions of portions are not necessarily the same as the actual values thereof. In the specification and drawings, components similar to those described in regard to a drawing thereinabove are marked with like reference numerals, and a detailed description is omitted as appropriate.

In the description of the embodiments, an XYZ orthogonal coordinate system is used. A direction from a drain electrode 41 toward a source electrode 42 is taken as a Z-direction. Two mutually-orthogonal directions perpendicular to the Z-direction are taken as an X-direction and a Y-direction.

Terms and the like, such as “parallel” and “same”, used in the specification to specify shapes or geometrical conditions and the degrees thereof are not limited to their strict meanings and are construed as including the extent to which similar functions can be expected.

In the following descriptions and drawings, notations of n⁺, n, n− and p⁺, p, p⁻ represent relative heights of impurity concentrations in conductivity types. That is, the notation with “+” shows a relatively higher impurity concentration than an impurity concentration for the notation without any of “+” and “−”, and the notation with “−” shows a relatively lower impurity concentration than the impurity concentration for the notation without any of them. These notations represent relative height of a net impurity concentration after mutual compensation of these impurities when respective regions include both of a p-type impurity and an n-type impurity. The embodiments described below may be implemented by reversing the p-type and the n-type of each of the semiconductor regions.

### 1. Structure of Semiconductor Device 100

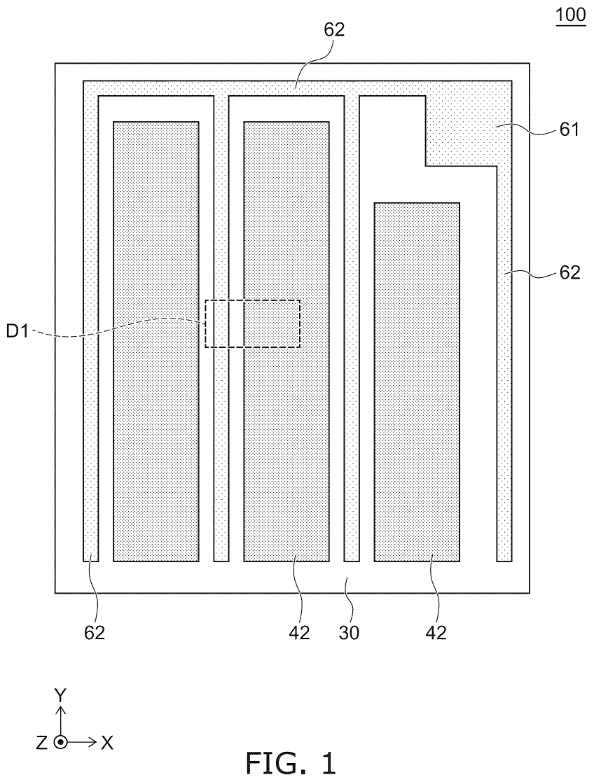

A semiconductor device 100 according to an embodiment will be described with reference to FIG. 1 to FIG. 10.

FIG. 1 is a plan view of the semiconductor device according to the embodiment.

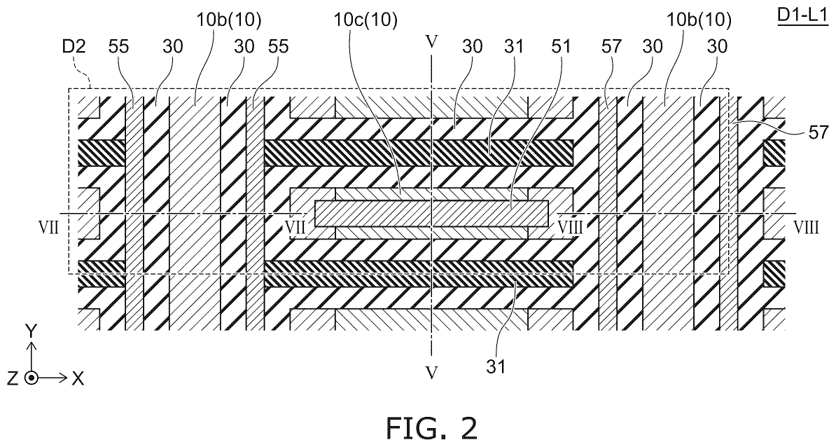

FIG. 2 is a cross-sectional view of a region D1 at a height L1.

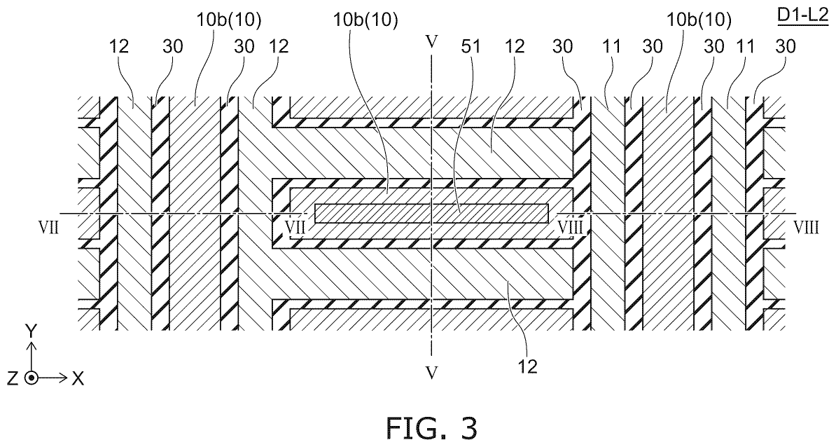

FIG. 3 is a cross-sectional view of the region D1 at a height L2.

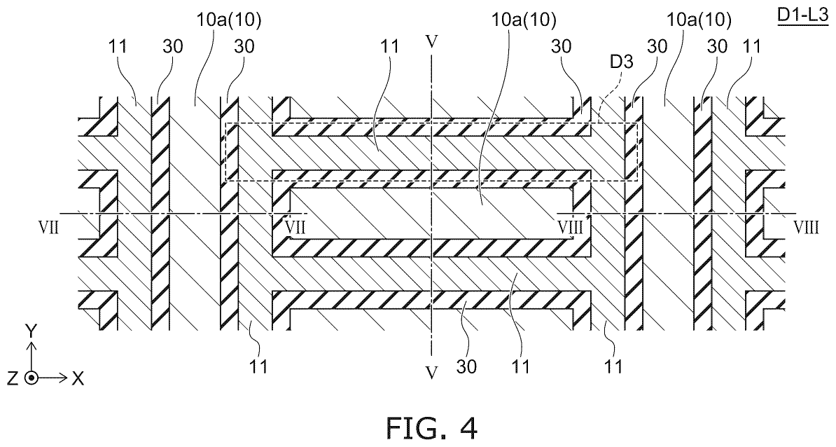

FIG. 4 is a cross-sectional view of the region D1 at a height L3.

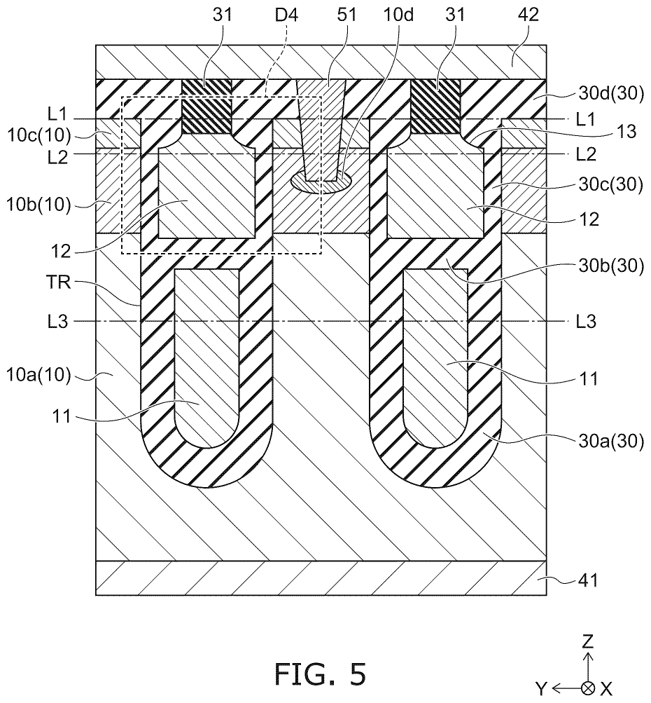

FIG. 5 is a cross-sectional view taken along line V-V in FIG. 2 to FIG. 4.

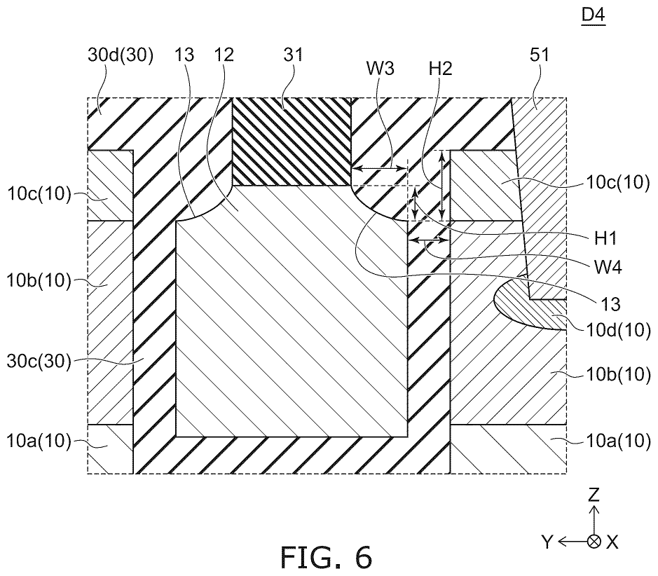

FIG. 6 is an enlarged view of a region D4.

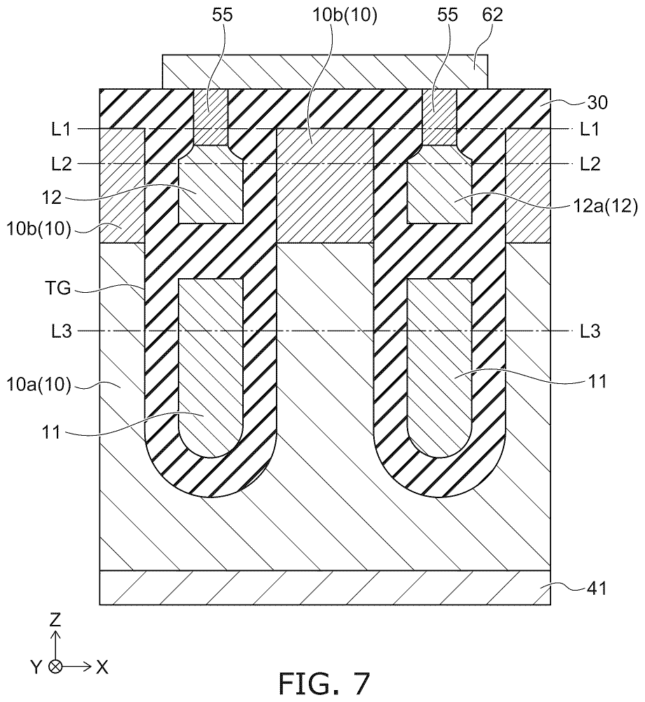

FIG. 7 is a cross-sectional view taken along line VII-VII in FIG. 2 to FIG. 4.

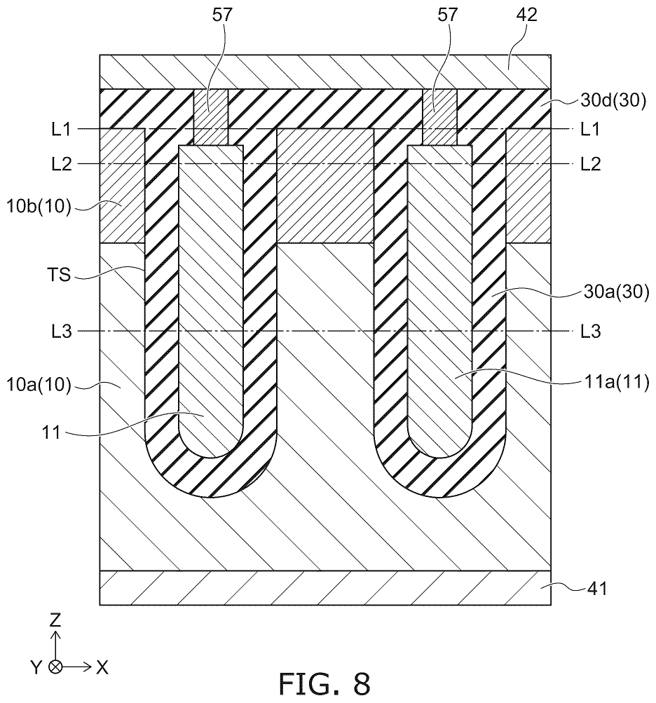

FIG. 8 is a cross-sectional view taken along line VIII-VIII in FIG. 2 to FIG. 4.

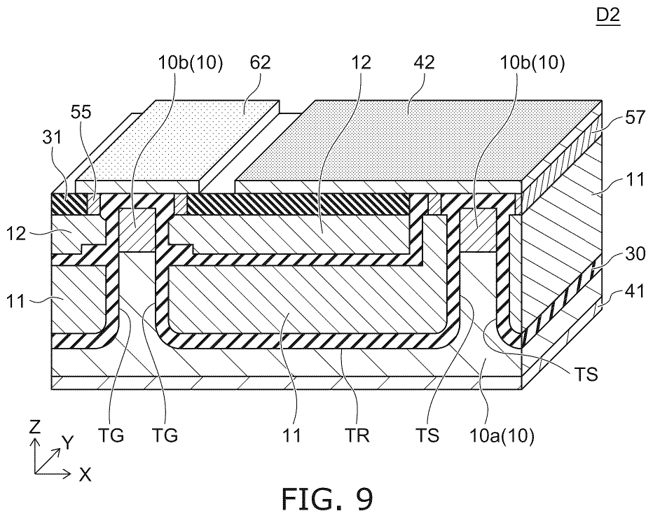

FIG. 9 is a perspective view schematically showing a region D2.

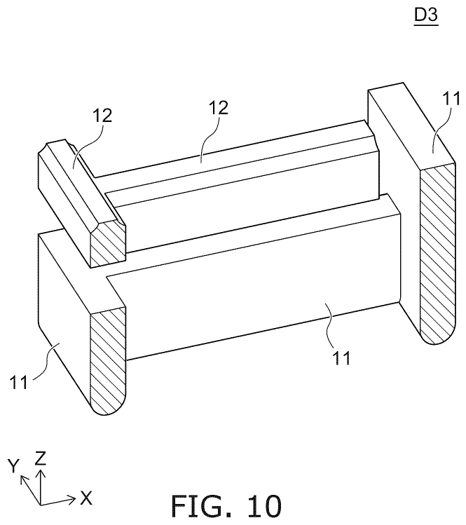

FIG. 10 is a perspective view schematically showing a structure of a part of a region D3.

The semiconductor device 100 is, for example, a power MOSFET. As shown in FIG. 1, on the upper surface of the semiconductor device 100, a source electrode 42, which is a second electrode, a gate pad 61, and a gate wiring 62 are disposed. On the entire lower surface of the semiconductor device 100A, a drain electrode 41, which is a first electrode, is disposed.

The source electrode 42 is disposed in a rectangular shape having long sides in a second direction (Y-direction in the drawing, hereinafter simply referred to as Y-direction) in plan view. As an example, three source electrodes 42 are disposed on the upper surface of the semiconductor device 100, but the source electrode 42 is not limited to this example. The gate pad 61 is, for example, a rectangular shape. The gate pad 61 is disposed in a corner that is positioned at one end side in a first direction (X-direction in the drawing, hereinafter simply referred to as X-direction) and at one end side in the Y-direction in plan view. The first direction (X-direction) is orthogonal to the second direction. The gate wiring 62 is disposed to extend in the X-direction from the gate pad 61, and furthermore, is disposed to extend in the Y-direction so as to be adjacent to the source electrode 42. Note that the position where the gate pad 61 is disposed is not limited to this example.

As shown in FIG. 2 to FIG. 4, in the semiconductor device 100, a cell portion (a region having a structure shown in the V-V cross section), a gate finger portion (a region having a structure shown in the VII-VII cross section), and a source finger portion (a region having a structure shown in the VIII-VIII cross section) are set.

As shown in FIG. 5, in the cell portion, a semiconductor portion 10, the drain electrode 41, which is the first electrode, and the source electrode 42 are disposed.

The semiconductor portion 10 contains, for example, silicon, and is provided between the drain electrode 41 and the source electrode 42. The semiconductor portion 10 includes a first semiconductor layer 10a of a first conductivity type, a second semiconductor layer 10b of a second conductivity type, a third semiconductor layer 10c of the first conductivity type, and a fourth semiconductor layer 10d of the second conductivity type. As an example, a description will be given below while the first conductivity type is assumed to be the n-type and the second conductivity type is assumed to be the p-type, but the conductivity types are not limited to this.

The first semiconductor layer 10a includes, for example, an n⁺-type drift layer disposed on the upper surface of the drain electrode 41 and an n−-type drift layer disposed on the upper surface of the n⁺-type drift layer. The first semiconductor layer 10a extends between the drain electrode 41 and the source electrode 42.

The second semiconductor layer 10b is, for example, a p-type base layer. The second semiconductor layer 10b is provided on the first semiconductor layer 10a.

The third semiconductor layer 10c is, for example, an n⁺-type source layer. The third semiconductor layer 10c is provided partially on the second semiconductor layer 10b. The third semiconductor layer 10c is electrically connected to the source electrode 42.

The fourth semiconductor layer 10d is, for example, a p⁺-type contact layer. The fourth semiconductor layer 10d is provided partially on the second semiconductor layer 10b. The fourth semiconductor layer 10d contains a second-conductivity-type impurity having a higher concentration than a second-conductivity-type impurity of the second semiconductor layer 10b. The source electrode 42 is electrically connected to the second semiconductor layer 10b, the third semiconductor layer 10c, and the fourth semiconductor layer 10d via a source contact 51.

In the semiconductor portion 10, a plurality of trenches TR extending along the X-direction are formed. Each trench TR is, for example, formed in an elongated groove shape with a curved bottom, but is not limited to this example. In the trench TR, a field plate electrode 11, a gate electrode 12, and a first insulating portion 30 are disposed.

The field plate electrode 11 is provided so as to extend in the X-direction in the lower portion of the trench TR in the cell portion. Specifically, the field plate electrode 11 is disposed so as to face the first semiconductor layer 10a. The field plate electrode 11 is a conductor and is electrically connected to the source electrode 42 via a field plate contact 57 in the source finger portion as described below. The shape of the field plate electrode 11 on the ZX plane may be, for example, a semi-elliptic cylindrical shape that is vertically elongated and curved along the cross section of the trench TR, but is not limited to this example.

The gate electrode 12 is provided so as to extend in the X-direction in the upper portion of the trench TR in the cell portion. The gate electrode 12 may be, for example, polysilicon in which impurities are mixed into silicon. Specifically, the gate electrode 12 is disposed so as to face the second semiconductor layer 10b and the third semiconductor layer 10c. The gate electrode 12 has, at either end along the Y-direction, a facing surface 13. The facing surface 13 faces the third semiconductor layer 10c. The facing surface 13 is formed so as to be away from the third semiconductor layer 10c as the facing surface 13 extends upward. In other words, the distance between the facing surface 13 and the third semiconductor layer 10c increases as it extends upward. The shape of the gate electrode 12 below the facing surface 13 on the ZX plane may be, for example, a rectangular shape, but is not limited to this example. The facing surface 13 will be described in detail below.

The first insulating portion 30 contains silicon oxide (SiO₂) and is continuously provided inside the trench TR and on the semiconductor portion 10. Specifically, the first insulating portion 30 includes a field plate insulating portion 30a, an interlayer portion 30b, a gate insulating portion 30c, and an over-layer portion 30d.

The field plate insulating portion 30a is disposed around the lateral sides and the lower side of the field plate electrode 11 in order to insulate the field plate electrode 11 from the first semiconductor layer 10a. The interlayer portion 30b is disposed in a layer shape between the gate electrode 12 and the field plate electrode 11 in order to insulate the gate electrode 12 from the field plate electrode 11.

The gate insulating portion 30c is disposed around the lateral sides of the gate electrode 12 in order to insulate the gate electrode 12 from the second semiconductor layer 10b and the third semiconductor layer 10c. The over-layer portion 30d is disposed in a layer shape on the third semiconductor layer 10c in order to insulate the third semiconductor layer 10c from the gate electrode 12.

On top of the gate electrode 12, a second insulating portion 31 containing a material different from that of the first insulating portion 30 is disposed. The second insulating portion 31 contains, for example, silicon nitride (SiN), and insulates the gate electrode 12 and the source electrode 42 from each other. For example, the length (width) of the second insulating portion 31 in the Y-direction is shorter than the length of the gate electrode 12 in the Y-direction. A part of the second insulating portion 31 is arranged side-by-side with a part of the third semiconductor layer 10c in the Y-direction. The distance between the second insulating portion 31 and the third semiconductor layer 10c in the Y-direction is longer than the distance between the facing surface 13 and the third semiconductor layer 10c in the Y-direction.

As shown in FIG. 6, at either end along the Y-direction, the facing surface 13 is formed at a position facing the third semiconductor layer 10c so as to be away from the third semiconductor layer 10c as the facing surface 13 extends upward. The distance between the gate electrode 12 and the third semiconductor layer 10c in the Y-direction is longer than the distance between the gate electrode 12 and the second semiconductor layer 10b in the Y-direction. As an example, the facing surface 13 may be a curved surface as shown in FIG. 6, or as another example, may be a flat surface. The length (height H1) of the facing surface 13 in the Z-direction is smaller than the height H2 of the third semiconductor layer 10c in the Z-direction. The height H1 of the facing surface 13 in the Z-direction is preferably about H1/H2=½ relative to the height H2 of the third semiconductor layer 10c. The width W3 of the facing surface 13 in the Y-direction is preferably about W3/W4=⅓ relative to the distance W4 between the second semiconductor layer 10b and the gate electrode.

As shown in FIG. 7, in the gate finger portion, the drain electrode 41, the semiconductor portion 10, and the gate wiring 62 are disposed.

The semiconductor portion 10 in the gate finger portion includes the first semiconductor layer 10a of the first conductivity type and the second semiconductor layer 10b of the second conductivity type. In the semiconductor portion 10 in the gate finger portion, a pair of gate trenches TG extending along the Y-direction is formed. Each gate trench TG is, for example, formed in an elongated groove shape with a curved bottom, but is not limited to this example. In the gate trench TG, the field plate electrode 11, the gate electrode 12, and a gate contact 55 are disposed.

The gate contact 55 has conductivity and electrically connects the gate wiring 62 and a first coupling portion 12a of the gate electrode 12. Accordingly, a current flows from the gate wiring 62 to the gate electrode 12 through the first coupling portion 12a. The cross-sectional area (area on the XZ plane) S1 of the gate electrode 12 in the gate finger portion shown in FIG. 7 may be, for example, made smaller than the cross-sectional area (area on the YZ plane) S2 of the gate electrode 12 in the cell portion shown in FIG. 5. Around the field plate electrode 11 and the gate electrode 12, the first insulating portion 30 is disposed.

As shown in FIG. 8, in the source finger portion, the drain electrode 41, the semiconductor portion 10, and the source electrode 42 are disposed.

The semiconductor portion 10 in the source finger portion includes the first semiconductor layer 10a of the first conductivity type and the second semiconductor layer 10b of the second conductivity type. In the semiconductor portion 10 in the source finger portion, a pair of source trenches TS extending along the Y-direction is formed. Each source trench TS is, for example, formed in an elongated groove shape with a curved bottom, but is not limited to this example. In the source trench TS, the field plate electrode 11 and the field plate contact 57 are disposed.

The field plate contact 57 has conductivity and electrically connects the source electrode 42 and a second coupling portion 11a of the field plate electrode 11. Accordingly, current flows from the source electrode 42 to the field plate electrode 11. The field plate electrode 11 in the source finger portion has a semi-cylindrical shape that is vertically elongated and curved along the cross section of the source trench TS, and is disposed to extend from a position facing the first semiconductor layer 10a to a position facing the second semiconductor layer 10b. Around the field plate electrode 11, the first insulating portion 30 is disposed.

As shown in FIG. 9 and FIG. 10, in the source finger portion, the field plate electrode 11 is disposed to extend from a position facing the first semiconductor layer 10a to a position facing the second semiconductor layer 10b in the source trench TS, and in the cell portion and the gate finger portion, the field plate electrode 11 is disposed at a position facing the first semiconductor layer 10a in the trench TR or the gate trench TG. The gate electrode 12 is not disposed in the source finger portion. In the cell portion and the gate finger portion, the gate electrode 12 is disposed in the trench TR or the gate trench TG at a position facing the second semiconductor layer 10b and the third semiconductor layer 10c.

### 2. Method for Manufacturing Semiconductor Device 100

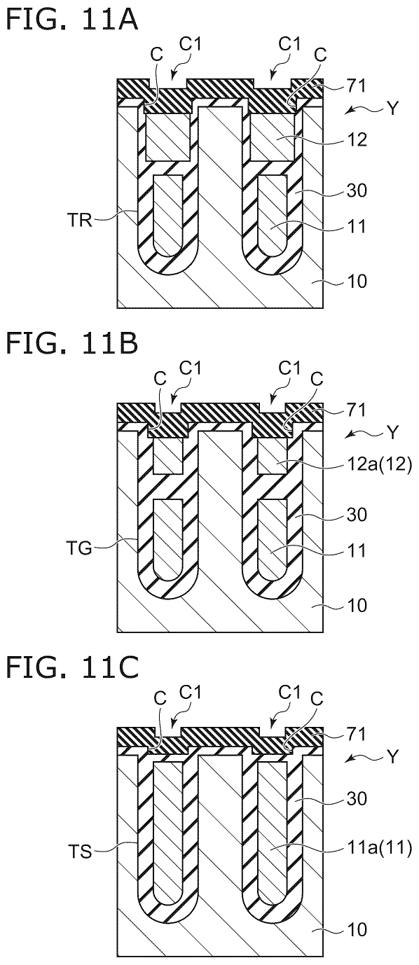

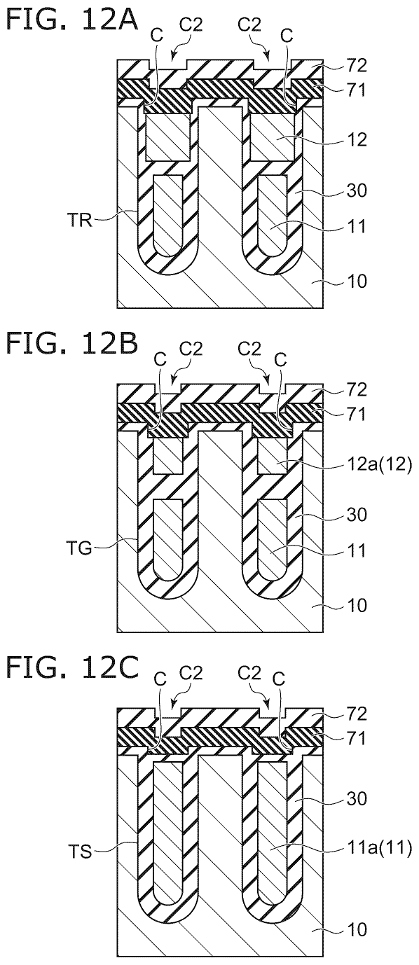

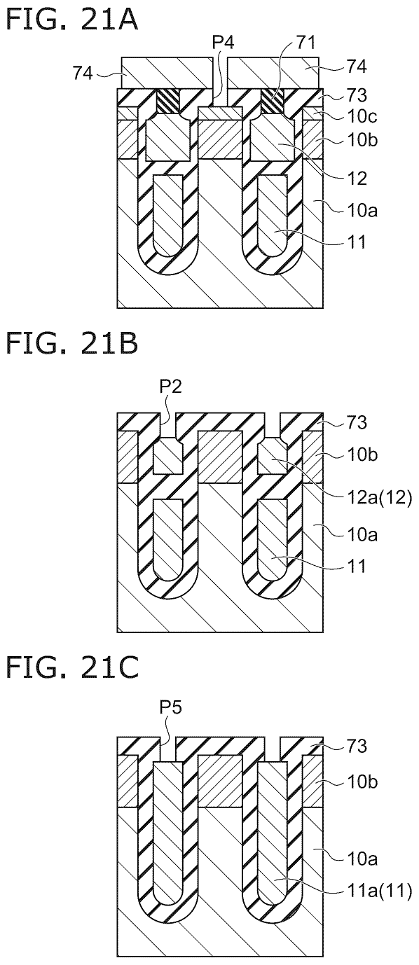

Hereinafter, a method for manufacturing the semiconductor device 100 according to the embodiment will be described with reference to FIG. 11A to FIG. 21C. In FIG. 11A to FIG. 21C, FIG. 11A, FIG. 12A, . . . , and FIG. 21A show the cell portion, FIG. 11B, FIG. 12B, . . . , and FIG. 21B show the gate finger portion, and FIG. 11C, FIG. 12C, . . . , and FIG. 21C show the source finger portion. In the following description, the trench TR in the cell portion, the gate trench TG in the gate finger portion, and the source trench TS in the source finger portion may be collectively and simply referred to as a trench.

First, as shown in FIGS. 11A to 11C, a structure Y is prepared. The structure Y includes the semiconductor portion 10, of the first conductivity type, having a trench formed therein with a known method, and containing silicon, the field plate electrode 11 and the gate electrode 12 provided in the trench, and the first insulating portion 30 disposed between the semiconductor portion 10 and the gate electrode 12, the structure Y having a recessed portion C formed on the gate electrode 12. On top of the structure Y, a silicon nitride film 71 is formed with, for example, a CVD (Chemical Vapor Deposition) method. Accordingly, a recess C1 reflecting the recessed portion C is formed on the upper surface of the silicon nitride film 71.

Next, as shown in FIGS. 12A to 12C, a silicon oxide film 72 is formed on the silicon nitride film 71 by CVD. Accordingly, a recess C2 reflecting the recess C1 is formed on the upper surface of the silicon oxide film 72.

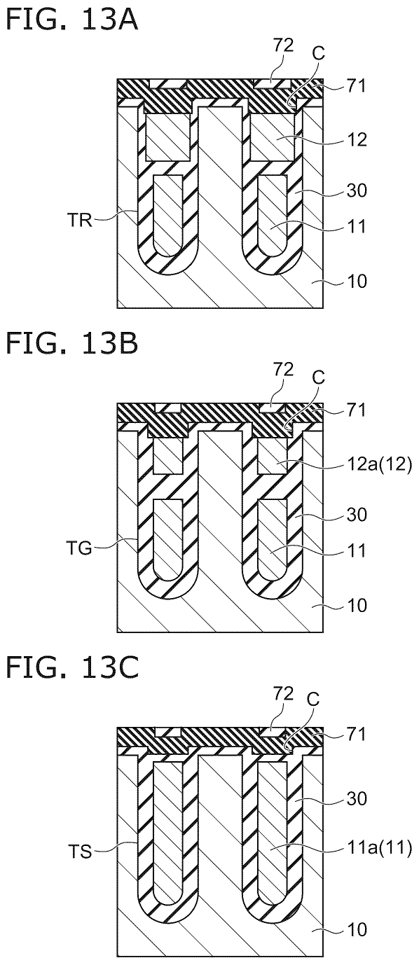

Next, as shown in FIGS. 13A to 13C, the silicon oxide film 72 is removed in a region other than a region immediately above the recessed portion C by performing a planarization process with, for example, CMP (Chemical Mechanical Polishing). Accordingly, the silicon oxide film 72 remains only in the region immediately above the recessed portion C.

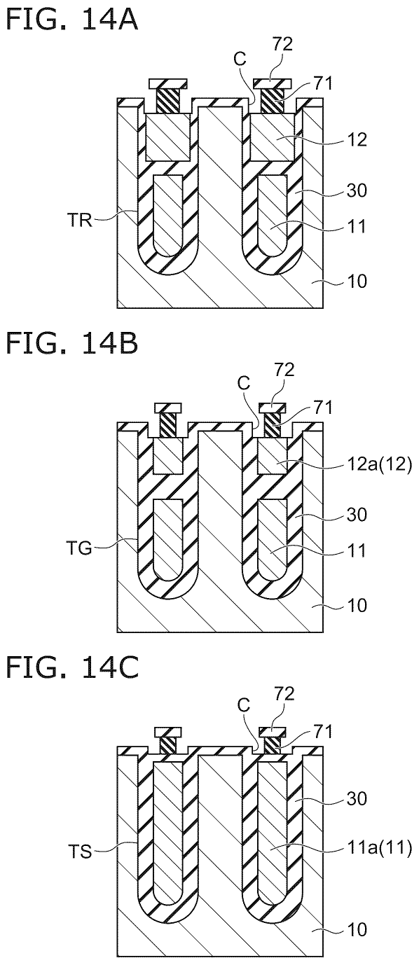

Next, as shown in FIGS. 14A to 14C, the silicon nitride film 71 is etched while the silicon oxide film 72 above the recessed portion C is used as a mask material. The etching may be anisotropic etching, such as RIE (Reactive Ion Etching). Accordingly, the silicon nitride film 71 remains only in the region immediately above the recessed portion C except for the peripheral portion. After the process of etching the silicon nitride film 71, the length of the silicon oxide film 72 in the Y-direction is longer than the length of the silicon nitride film 71 in the Y-direction.

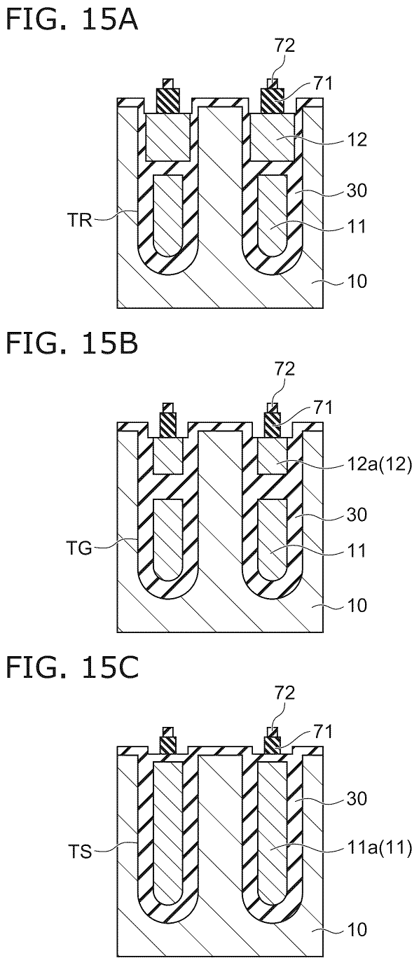

Next, as shown in FIGS. 15A to 15C, the silicon oxide film 72 formed on the silicon nitride film 71 is recessed by etching. Here, the etching may be isotropic etching, such as wet etching. Accordingly, the length of the silicon oxide film 72 formed on the silicon nitride film 71 in the width direction of the trench becomes shorter than the length of the silicon nitride film 71 in the width direction. Further, in the cell portion and the gate finger portion, the peripheral edge portion on the upper surface of the gate electrode 12 is exposed. After the process of etching the silicon oxide film 72, the length of the silicon oxide film 72 in the Y-direction is shorter than the length of the silicon nitride film 71 in the Y-direction. The length of the silicon oxide film 72 in the Z-direction is smaller than the length of the silicon nitride film 71 in the Z-direction.

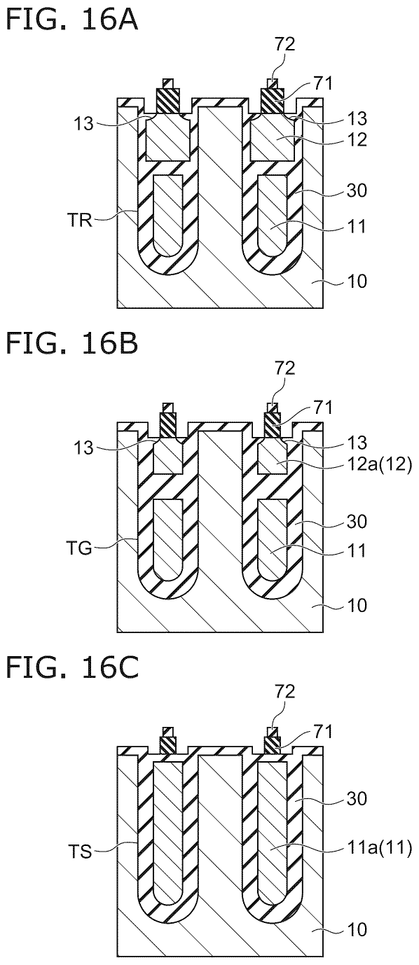

Next, as shown in FIGS. 16A to 16C, oxidation treatment is performed on the gate electrode 12. Accordingly, in the gate electrode 12 in the cell portion and in the gate finger portion, the exposed portion is oxidized and becomes a part of the first insulating portion 30. As a result, at the end portions of the gate electrode 12 in the cell portion and in the gate finger portion, the facing surface 13 is formed in a shape that is away from the semiconductor portion 10 as the facing surface 13 extends upward. After the oxidation treatment, the length of the upper portion of the gate electrode 12 in the Y-direction is shorter than the length of the lower portion of the gate electrode 12 in the Y-direction.

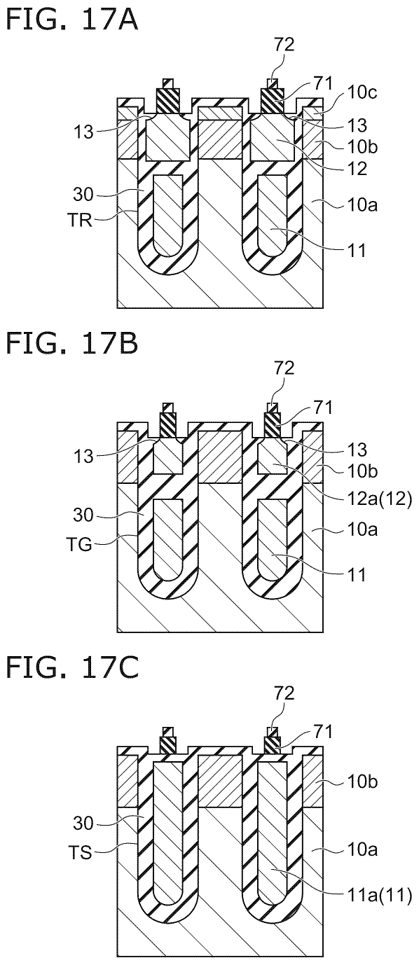

Next, as shown in FIGS. 17A to 17C, impurities are implanted into the upper portion of the semiconductor portion 10 in the cell portion, the gate finger portion, and the source finger portion to form the second semiconductor layer 10b of the second conductivity type. Further, impurities are implanted into the upper portion of the second semiconductor layer 10b in the cell portion to form the third semiconductor layer 10c of the first conductivity type. Accordingly, in the cell portion, the facing surface 13, which is the portion subjected to the oxidation treatment in the gate electrode 12, and the third semiconductor layer 10c of the first conductivity type face each other.

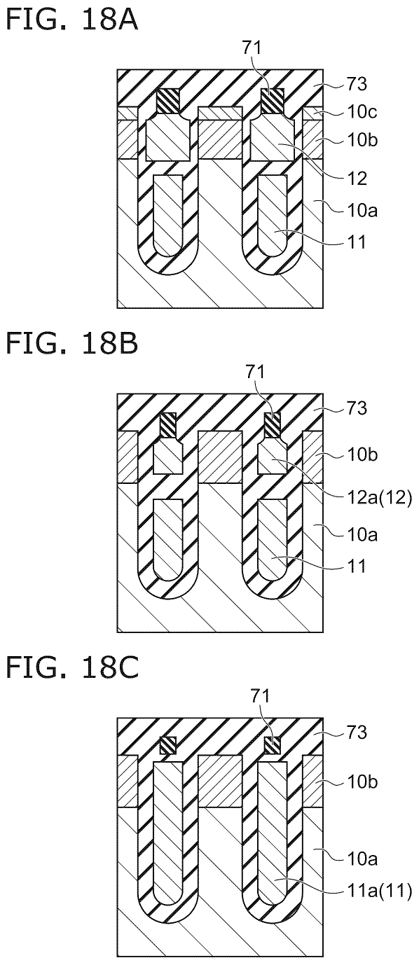

Next, as shown in FIGS. 18A to 18C, a silicon oxide film 73 is formed on the third semiconductor layer 10c in the cell portion and on the second semiconductor layer 10b in the gate finger portion and in the source finger portion with, for example, a CVD method.

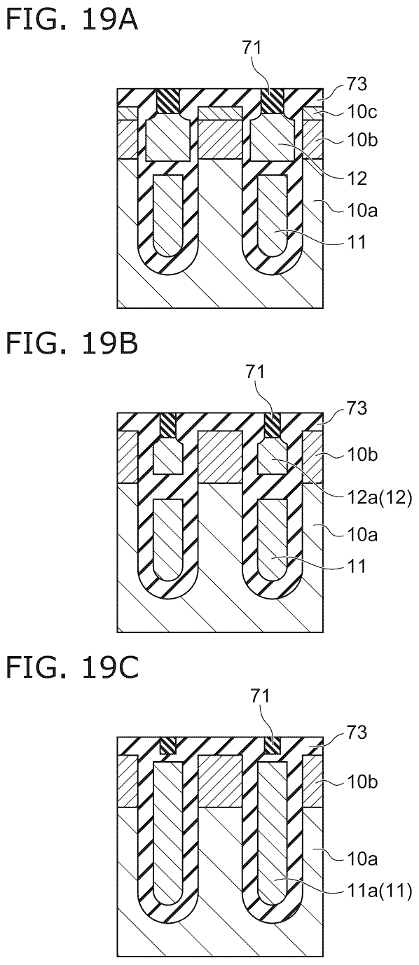

Next, as shown in FIGS. 19A to 19C, the silicon oxide film 73 is removed by performing a planarization process with CMP to expose the upper surface of the silicon nitride film 71 positioned above the field plate electrode 11 or the gate electrode 12.

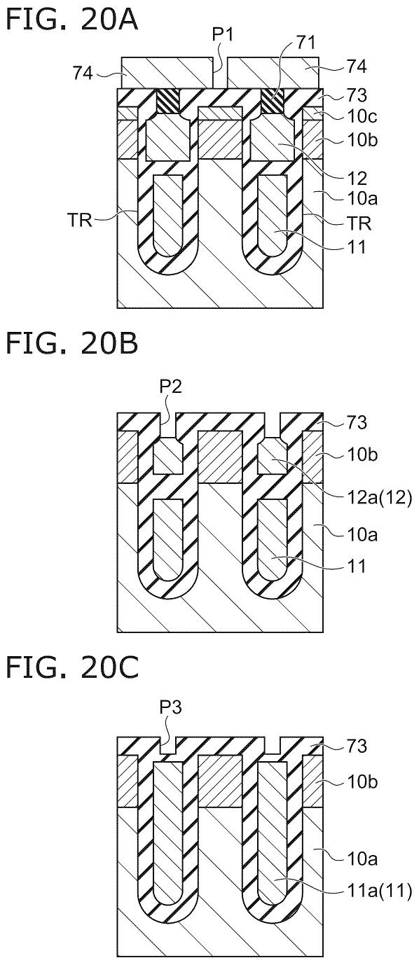

Next, as shown in FIGS. 20A to 20C, a resist pattern 74 in which a first opening P1 is formed between the plurality of trenches TR is formed on the silicon oxide film 73. In the gate finger portion, the gate electrode 12 includes the first coupling portion 12a coupled to the gate wiring 62 provided on the upper surface of the semiconductor device 100, and the resist pattern 74 is formed without covering the first coupling portion 12a. In the source finger portion, the field plate electrode 11 includes the second coupling portion 11a coupled to the source electrode 42 provided on the upper surface of the semiconductor device 100, and the resist pattern 74 is formed without covering the second coupling portion 11a.

RIE is performed on the silicon nitride film 71 while the resist pattern 74 is used as a mask. Accordingly, the silicon nitride film 71 disposed on the first coupling portion 12a is removed, and a second opening P2 for disposing the gate contact 55 is formed. Further, the silicon nitride film 71 disposed above the second coupling portion 11a is removed, and a third opening P3 is formed.

Next, as shown in FIGS. 21A to 21C, RIE is performed on the silicon oxide film 73 while the resist pattern 74 is used as a mask. Accordingly, in the cell portion, a fourth opening P4 for disposing the source contact 51 is formed. Further, in the source finger portion, the silicon oxide film 73 disposed on the second coupling portion 11a is removed, and a fifth opening P5 for disposing the field plate contact 57 is formed.

Thereafter, the source contact 51 is disposed in the fourth opening P4 in the cell portion. The drain electrode 41, which is the first electrode, is provided on the lower surface of the semiconductor portion 10, and the source electrode 42, which is the second electrode, is provided on the upper surface of the semiconductor portion 10. Accordingly, the semiconductor device 100 is manufactured.

### 3. Summation

As described above, the semiconductor device 100 according to the embodiment includes: the drain electrode 41, which is the first electrode; the semiconductor portion 10 including the first semiconductor layer 10a, of the first conductivity type, provided on the drain electrode 41 and connected to the drain electrode 41, the second semiconductor layer 10b, of the second conductivity type, provided on the first semiconductor layer, and the third semiconductor layer 10c, of the first conductivity type, provided on the second semiconductor layer, the semiconductor portion 10 having a trench formed therein and extending along the X-direction, which is the first direction, and containing silicon; the gate electrode disposed in the trench so as to face the second semiconductor layer 10b and the third semiconductor layer 10c along the Y-direction, which is the second direction, orthogonal to the X-direction, the gate electrode having the facing surface 13 at either end along the Y-direction, the facing surface 13 being formed at a position facing the third semiconductor layer 10c so as to be away from the third semiconductor layer 10c as the facing surface 13 extends upward; the first insulating portion 30 continuously provided on the semiconductor portion 10 and inside the trench TR, and containing silicon oxide; the second insulating portion 31 provided on the gate electrode 12 and containing silicon nitride different in material from the first insulating portion 30; and the source electrode 42, which is the second electrode, provided on the semiconductor portion 10 and connected to the second semiconductor layer 10b and the third semiconductor layer 10c.

With such a configuration, the third semiconductor layer 10c of the first conductivity type and the gate electrode 12 can be spaced apart from each other in the Y-direction while the height H1 for which the third semiconductor layer 10c and the gate electrode 12 face each other is maintained. Therefore, the parasitic capacitance between the third semiconductor layer 10c and the gate electrode 12 can be reduced while maintaining the advantageous influence of the gate electrode 12 over the second semiconductor layer 10b. As a result, it is possible to suppress an increase in Ron while reducing Qg.

Further, the method for manufacturing the semiconductor device 100 includes: the process of forming the silicon nitride film 71 on the structure Y, the structure Y including the semiconductor portion 10 having the trench TR formed therein and extending along the Y-direction, the semiconductor portion 10 containing silicon, the gate electrode 12 provided in the trench TR and containing silicon, and the first insulating portion 30 disposed between the semiconductor portion 10 and the gate electrode 12, the structure Y having the recessed portion C formed on the gate electrode 12; the process of forming the silicon oxide film 72 on the silicon nitride film 71; the process of removing the silicon oxide film 72 in a region other than a region immediately above the recessed portion C by performing a planarization process; the process of etching the silicon nitride film 71 while using the silicon oxide film 72 above the recessed portion C as a mask; the process of etching the silicon oxide film 72; the process of performing oxidation treatment on the gate electrode 12; the process of implanting impurities into the semiconductor portion 10 to form the upper portion of the semiconductor portion 10 as the second semiconductor layer 10b of the second conductivity type; the process of implanting impurities into the semiconductor portion 10 to form the upper portion of the second semiconductor layer 10b, the upper portion facing a portion subjected to the oxidation treatment in the gate electrode 12, as the third semiconductor layer 10c of the first conductivity type; the process of forming the silicon oxide film 73 on the third semiconductor layer 10c; the process of exposing the silicon nitride film 71 by performing a planarization process; the process of forming the resist pattern 74 having the first opening P1 formed between the plurality of trenches TR; and the process of etching the silicon oxide film 73 while using the resist pattern 74 as a mask. In the process of forming the resist pattern 74, the resist pattern 74 does not cover the first coupling portion 12a, and the method further includes, after the process of forming the resist pattern 74, the process of removing the silicon nitride film 71 disposed on the first coupling portion 12a. In the process of forming the resist pattern 74, the resist pattern does not cover the second coupling portion 11a, in the process of removing the silicon nitride film 71, the silicon nitride film 71 disposed above the second coupling portion 11a is also removed, and the method further includes, after the process of removing the silicon nitride film 71, the process of removing the silicon oxide film 73 disposed on the second coupling portion 11a. The method further includes: the process of providing the drain electrode 41, which is the first electrode, on the lower surface of the semiconductor portion 10; and the process of providing the source electrode 42, which is the second electrode, on the upper surface of the semiconductor portion 10.

With such processes, the silicon nitride film 71 is used as a stopper film in the planarization process with CMP to improve the flatness of the interlayer film, and consequently, die shrink of the semiconductor device 100 can be realized and an increase in Ron can be reduced.

Specifically, with the above-described configuration, in the process of forming the resist pattern 74, the focus margin can be improved, the width of the fourth opening P4 for disposing the source contact 51 can be narrowed, and die shrink of the semiconductor device 100 can be realized. Further, with the above-described configuration, the fourth opening P4 for disposing the source contact 51, the second opening P2 for disposing the gate contact 55, and the fifth opening P5 for disposing the field plate contact 57 can be formed in the same process. Further, the first opening P1 is formed between the plurality of trenches TR by forming the resist pattern 74, and therefore, misalignment due to self-alignment of the first opening P1 can be prevented.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

### The Invention Includes the Following Forms.

### Appendix 1

A semiconductor device comprising:
a first electrode;
a semiconductor portion provided on the first electrode and having a trench formed therein, the trench extending along a first direction, the semiconductor portion including
   a first semiconductor layer of a first conductivity type connected to the first electrode,
   a second semiconductor layer of a second conductivity type provided on the first semiconductor layer, and
   a third semiconductor layer of the first conductivity type provided on the second semiconductor layer;
a gate electrode disposed in the trench, the gate electrode facing the second semiconductor layer and the third semiconductor layer along a second direction orthogonal to the first direction, the gate electrode having a facing surface formed at a position facing the third semiconductor layer, a distance between the facing surface and the third semiconductor layer in the second direction increasing as it extends upward;
a first insulating portion continuously provided on the semiconductor portion and inside the trench;
a second insulating portion provided on the gate electrode, a material of the second insulating portion being different from a material of the first insulating portion; and
a second electrode provided on the semiconductor portion and connected to the second semiconductor layer and the third semiconductor layer.

### Appendix 2

The semiconductor device according to appendix 1, in which

the gate electrode has the facing surface at either end along the second direction.

### Appendix 3

The semiconductor device according to appendix 1, in which
the semiconductor portion contains silicon,
the first insulating portion contains silicon oxide, and
the second insulating portion contains silicon nitride.

### Appendix 4

A method for manufacturing a semiconductor device, including:
forming a silicon nitride film on a structure, the structure including a semiconductor portion having a trench formed therein, the trench extending along a first direction, the semiconductor portion containing silicon, a gate electrode provided in the trench and containing silicon, and an insulating portion disposed between the semiconductor portion and the gate electrode, the structure having a recessed portion formed on the gate electrode;
forming a silicon oxide film on the silicon nitride film;
removing the silicon oxide film in a region other than a region immediately above the recessed portion by performing a planarization process;
etching the silicon nitride film while using the silicon oxide film above the recessed portion as a mask; and performing oxidation treatment on the gate electrode.

### Appendix 5

The method according to appendix 4, further including:
after the etching of the silicon nitride film, etching the silicon oxide film.

### Appendix 6

The method according to appendix 4 or 5, in which
the semiconductor portion is of a first conductivity type, and
the method further comprises: after the performing of oxidation treatment on the gate electrode,
implanting an impurity into the semiconductor portion to form an upper portion of the semiconductor portion as a second semiconductor layer of a second conductivity type;
implanting an impurity into the semiconductor portion to form an upper portion of the second semiconductor layer, the upper portion facing a portion subjected to the oxidation treatment in the gate electrode, as a third semiconductor layer of the first conductivity type;
forming a silicon oxide film on the third semiconductor layer; and
exposing the silicon nitride film by performing a planarization process.

### Appendix 7

The method according to appendix 6, further including:
after the exposing,
forming a resist pattern having an opening formed between a plurality of the trenches; and
etching the silicon oxide film while using the resist pattern as a mask.

### Appendix 8

The method according to appendix 7, in which
the gate electrode includes a first coupling portion connected to a gate wiring provided on an upper surface of the semiconductor device,
in the forming of the resist pattern, the resist pattern does not cover the first coupling portion, and
the method further comprises, after the forming of the resist pattern, removing the silicon nitride film disposed on the first coupling portion.

### Appendix 9

The method according to appendix 8, in which
a field plate electrode is provided below the gate electrode in the trench,
the field plate electrode includes a second coupling portion coupled to a source electrode provided on the upper surface of the semiconductor device,
in the forming of the resist pattern, the resist pattern does not cover the second coupling portion,
in the removing of the silicon nitride film, the silicon nitride film disposed above the second coupling portion is also removed, and
the method further comprises: after the removing of the silicon nitride film, removing the silicon oxide film disposed on the second coupling portion.

### Appendix 10

The method according to any one of appendixes 4 to 9, further including:
providing a first electrode on a lower surface of the semiconductor portion; and
providing a second electrode on an upper surface of the semiconductor portion.

What is claimed is:

1. A semiconductor device comprising:
a first electrode;
a semiconductor portion provided on the first electrode and having a trench formed therein, the trench extending along a first direction, the semiconductor portion including
a first semiconductor layer of a first conductivity type connected to the first electrode,
a second semiconductor layer of a second conductivity type provided on the first semiconductor layer, and
a third semiconductor layer of the first conductivity type provided on the second semiconductor layer;
a gate electrode disposed in the trench, the gate electrode facing the second semiconductor layer and the third semiconductor layer along a second direction orthogonal to the first direction, the gate electrode having a facing surface formed at a position facing the third semiconductor layer, a distance between the facing surface and the third semiconductor layer in the second direction increasing as it extends upward;
a first insulating portion continuously provided on the semiconductor portion and inside the trench;
a second insulating portion provided on the gate electrode, a material of the second insulating portion being different from a material of the first insulating portion; and
a second electrode provided on the semiconductor portion and connected to the second semiconductor layer and the third semiconductor layer.

2. The semiconductor device according to claim 1, wherein
the gate electrode has the facing surface at either end along the second direction.

3. The semiconductor device according to claim 1, wherein
the semiconductor portion contains silicon,
the first insulating portion contains silicon oxide, and
the second insulating portion contains silicon nitride.

4. The semiconductor device according to claim 1, wherein
a distance between the gate electrode and the third semiconductor layer in the second direction is longer than a distance between the gate electrode and the second semiconductor layer in the second direction.

5. The semiconductor device according to claim 1, wherein
a length of the second insulating portion in the second direction is shorter than a length of the gate electrode in the second direction.

6. The semiconductor device according to claim 1, wherein
a part of the second insulating portion is arranged side-by-side with a part of the third semiconductor layer in the second direction.

7. The semiconductor device according to claim 1, wherein
a distance between the second insulating portion and the third semiconductor layer in the second direction is longer than a distance between the facing surface and the third semiconductor layer in the second direction.

8. The semiconductor device according to claim 1, wherein
a length of the facing surface in a third direction orthogonal to the first direction and the second direction is shorter than a length of the third semiconductor layer in the third direction.

9. The semiconductor device according to claim 1, further comprising:
a field plate electrode provided below the gate electrode, wherein
the first insulating portion is provided between the field plate electrode and the semiconductor portion.

10. A method for manufacturing a semiconductor device, comprising:
forming a silicon nitride film on a structure, the structure including a semiconductor portion having a trench formed therein, the trench extending along a first direction, the semiconductor portion containing silicon, a gate electrode provided in the trench and containing silicon, and an insulating portion disposed between the semiconductor portion and the gate electrode, the structure having a recessed portion formed on the gate electrode;
forming a silicon oxide film on the silicon nitride film;
removing the silicon oxide film in a region other than a region immediately above the recessed portion by performing a planarization process;
etching the silicon nitride film while using the silicon oxide film above the recessed portion as a mask; and
performing oxidation treatment on the gate electrode.

11. The method according to claim 10, wherein
after the oxidation treatment, a length of an upper portion of the gate electrode in a second direction orthogonal to the first direction is shorter than a length of a lower portion of the gate electrode in the second direction.

12. The method according to claim 10, wherein
after the etching of the silicon nitride film, a length of the silicon oxide film in a second direction orthogonal to the first direction is longer than a length of the silicon nitride film in the second direction.

13. The method according to claim 10, further comprising:
after the etching of the silicon nitride film, etching the silicon oxide film.

14. The method according to claim 13, wherein
after the etching of the silicon oxide film, a length of the silicon oxide film in a second direction orthogonal to the first direction is shorter than a length of the silicon nitride film in the second direction.

15. The method according to claim 14, wherein
after the etching of the silicon oxide film, a length of the silicon oxide film in a third direction orthogonal to the first direction and the second direction is smaller than a length of the silicon nitride film in the third direction.

16. The method according to claim 10, wherein
the semiconductor portion is of a first conductivity type, and
the method further comprises: after the performing of oxidation treatment on the gate electrode,
implanting an impurity into the semiconductor portion to form an upper portion of the semiconductor portion as a second semiconductor layer of a second conductivity type;
implanting an impurity into the semiconductor portion to form an upper portion of the second semiconductor layer, the upper portion facing a portion subjected to the oxidation treatment in the gate electrode, as a third semiconductor layer of the first conductivity type;
forming a silicon oxide film on the third semiconductor layer; and
exposing the silicon nitride film by performing a planarization process.

17. The method according to claim 16, further comprising:
after the exposing,
forming a resist pattern having an opening formed between a plurality of the trenches; and
etching the silicon oxide film while using the resist pattern as a mask.

18. The method according to claim 17, wherein
the gate electrode includes a first coupling portion connected to a gate wiring provided on an upper surface of the semiconductor device,
in the forming of the resist pattern, the resist pattern does not cover the first coupling portion, and
the method further comprises, after the forming of the resist pattern, removing the silicon nitride film disposed on the first coupling portion.

19. The method according to claim 18, wherein
a field plate electrode is provided below the gate electrode in the trench,
the field plate electrode includes a second coupling portion coupled to a source electrode provided on the upper surface of the semiconductor device,
in the forming of the resist pattern, the resist pattern does not cover the second coupling portion,
in the removing of the silicon nitride film, the silicon nitride film disposed above the second coupling portion is also removed, and
the method further comprises: after the removing of the silicon nitride film, removing the silicon oxide film disposed on the second coupling portion.

20. The method according to claim 10, further comprising:
providing a first electrode on a lower surface of the semiconductor portion; and
providing a second electrode on an upper surface of the semiconductor portion.
